(19) United States
(12) Patent Application Publication
(10) Pub. No.: US 2005/0142830 A1
(43) Pub. Date: Jun. 30, 2005

(54) Method for forming a contact of a semiconductor device

(75) Inventor: Seung Bum Kim, Seoul (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 10/998,817

(22) Filed: Nov. 30, 2004

(30) Foreign Application Priority Data
Dec. 24, 2003 (KR) 10-2003-0096377

(51) Int. Cl. H01L 21/4763; H01L 21/336; H01L 21/8238; H01L 21/8242

(52) U.S. Cl. 438/597; 438/279; 438/257; 438/253; 438/233

(57) ABSTRACT

A method for forming a contact of a semiconductor device is provided, including etching a predetermined thickness of an interlayer insulating film with a first self-aligned contact (SAC) etching process, exposing an etch barrier layer with a second SAC etching process, and etching the etch barrier layer to form the contact hole. Preferably, the first SAC etching process and the second SAC etching process use a photoresist film pattern as an etching mask.

### CORRESPONDING RELATED APPLICATION

This application claims the benefit of and priority to Korean patent application no. KR10-2003-0096377 filed on Dec. 24, 2003, the entire contents of which are incorporated by reference herein in its entirety.

### BACKGROUND OF THE INVENTION

1. Field of the Invention

The present invention generally relates to a method for forming a contact of a semiconductor device, and more specifically, to a method for forming a contact of a semiconductor device wherein a self-aligned contact (SAC) etching process is performed in two (or more) steps to form a contact hole having a stable characteristic, thereby improving the characteristics and reliability of the semiconductor device.

2. Description of the Related Art

FIGS. 1 and 2 are cross-sectional views illustrating a contact hole in a semiconductor device.

Referring to FIG. 1, a device isolation film (not shown) defining an active region is formed on a semiconductor substrate. Thereafter, a stacked structure of a gate oxide film, a gate conductive layer and a hard mask layer having a thickness of 4000 Å is formed thereon. Next, the stacked structure is etched via a photolithography and etching process using a gate mask (not shown) to form a gate. An etch barrier layer is then formed on the entire surface of the semiconductor substrate including the gate having an insulating film spacer on a sidewall thereof.

Thereafter, a planarized interlayer insulating film and an anti-reflective coating are subsequently deposited.

A photoresist film pattern (not shown) is then formed on the anti-reflective coating via an exposure and development process using a contact mask. A landing plug contact mask may be used as the contact mask.

Thereafter, the anti-reflective coating, the interlayer insulating film, and the etch barrier layer are sequentially etched using the photoresist film pattern as an etching mask to form a contact hole. At this point, the gate conductive layer is exposed as shown in FIG. 1 due to the damage to the shoulder of the insulating film spacer on a sidewall of the gate. As a result, a short circuit may be induced in the subsequent process.

Moreover, the interlayer insulating film in the lower portion of the contact hole is not completely etched, whereby the interlayer insulating film may remain at the bottom of the contact hole as shown in FIG. 2.

Due, in part, to shrinkage of a contact hole as the integration density is increased, it is difficult to form a conductive material filling up the contact hole in a subsequent process. Moreover, during the etching process of the interlayer insulating film, the shoulder of the insulating film spacer on the sidewall of the gate may be damaged and/or the interlayer insulating film at the bottom of the contact hole may not be completely removed, thereby degrading the contact characteristic of the device and deteriorating the characteristic and reliability of the device. As a result, fabrication of highly integrated semiconductor devices is difficult, if not possible. Thus, a need exists for an improved method for forming a contact of a semiconductor device.

Other problems with the prior art not described above can also be overcome using the teachings of the present invention, as would be readily apparent to one of ordinary skill in the art after reading this disclosure.

### SUMMARY OF THE INVENTION

An embodiment of the present invention provides a method for forming a contact of a semiconductor device wherein a SAC etching process having two (or more) separate steps is performed to form a contact hole having a predetermined size so as to improve the characteristic and reliability of the device and achieve high integration density of the device.

Another embodiment of the present invention provides a method for forming a contact of a semiconductor device comprising sequentially depositing a gate oxide film, a gate conductive layer, and a hard mask layer over a semiconductor substrate to form a stacked structure, etching the stacked structure of the gate oxide film, the gate conductive layer, and the hard mask layer to form a gate, forming an etch barrier layer on a surface of the substrate including the gate, sequentially depositing a planarized interlayer insulating film and an anti-reflective coating, forming a photoresist film pattern exposing a contact region on the anti-reflective coating, etching the anti-reflective coating using the photoresist film pattern as an etching mask, performing a first SAC etching process using the photoresist film pattern as an etching mask to etch a predetermined thickness of the interlayer insulating film, performing a second SAC etching process using the photoresist film pattern as an etching mask to expose the etch barrier layer, and etching the etch barrier layer to form a contact hole.

### BRIEF DESCRIPTION OF THE DRAWINGS

FIGS. 1 and 2 are cross-sectional views illustrating contact hole in a semiconductor device.

FIG. 3 is a cross-sectional view illustrating a method for forming a contact of a semiconductor device according to an embodiment of the present invention.

FIGS. 4a through 4d are cross-sectional views illustrating contact hole formed according to an embodiment of the present invention.

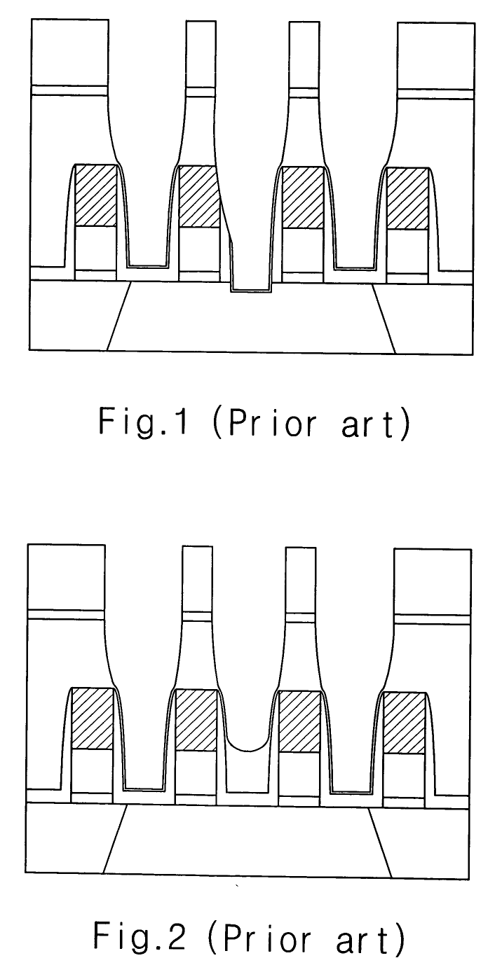

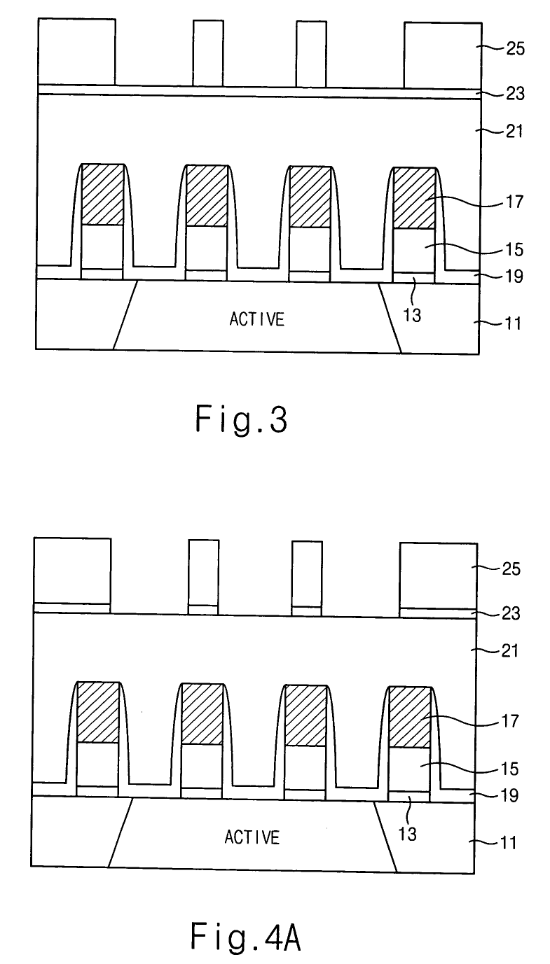

### DETAILED DESCRIPTION OF THE EXEMPLARY EMBODIMENTS

Reference will now be made in detail to exemplary embodiments of the present invention. Wherever possible, the same reference numbers will be used throughout the drawings to refer to the same or like parts.

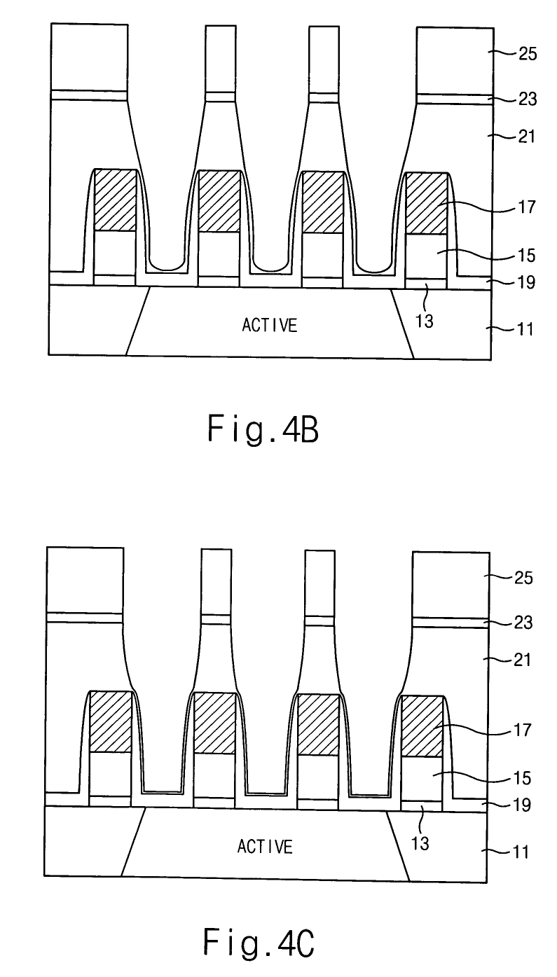

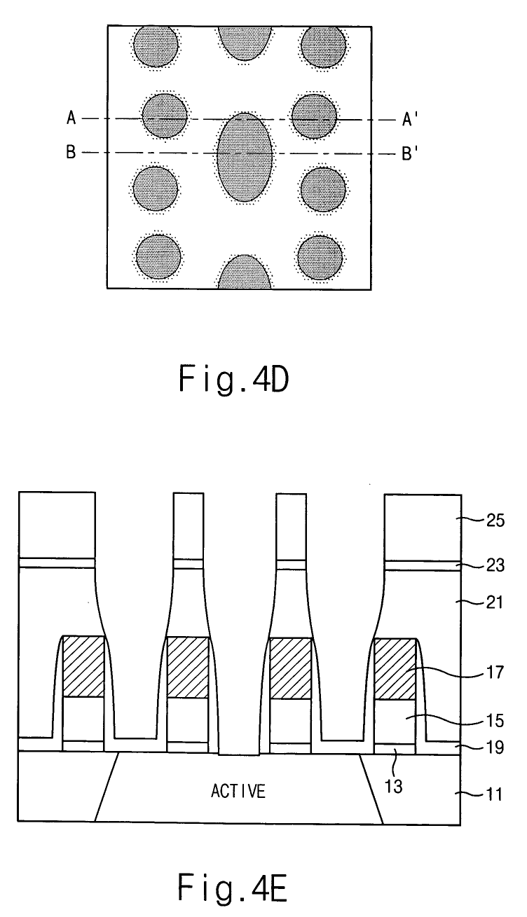

FIG. 3 schematically illustrates a method for forming a contact of a semiconductor device according to an embodiment of the present invention, and FIGS. 4a through 4e are cross-sectional views illustrating contact holes formed according to various embodiments of the present invention.

Referring to FIG. 3, a device isolation film defining an active region is formed on a semiconductor substrate 11. A stacked structure of a gate oxide film 13, a gate conductive layer 15 and a hard mask layer 17 is then formed on the semiconductor substrate 11. The stacked structure preferably has a thickness of about 4000 Å.

Next, the stacked structure is etched via a photolithography and etching process using a gate mask (not shown) to form a gate. Thereafter, an insulating film spacer is formed on a sidewall of the gate. Here, the gate comprises a word line or a bit line having an insulating film spacer on a sidewall thereof.

Thereafter, an etch barrier layer 19 is formed on substantially the entire surface of the semiconductor substrate 11 including the gate. Here, the insulating film spacer may comprise a nitride film.

A planarized interlayer insulating film 21 and an anti-reflective coating 23 are then sequentially deposited.

Thereafter, a photoresist film pattern 25 exposing a contact region is formed on the anti-reflective coating 23 via an exposure and development process using a contact mask (not shown). Here, a landing plug contact mask may be used as the contact mask.

Referring to FIG. 4a, the anti-reflective coating 23 is etched using the photoresist film pattern 25 as an etching mask.

Preferably, the etching process of the anti-reflective coating 23 is performed under a pressure of about 15 mTorr, at a top electrode power of about 1500 w and a bottom electrode power of about 500 w. In addition, the etching process may be performed using CHF₃ gas having a flow rate of about 12 sccm, O₂ gas having a flow rate of about 12 sccm, and/or Ar gas having a flow rate of about 300 sccm.

In addition, the etching process of the anti-reflective coating is preferably performed at a temperature of upper portion of a chamber ranging from about 58° C. to about 62° C., a temperature of sidewall of the chamber ranging from about 48° C. to about 52° C., and/or at a temperature of an electrode ranging from about 38° C. to about 42° C.

Referring to FIG. 4b, a first SAC etching process is preformed using the photoresist film pattern 25 as an etching mask.

The first SAC etching process is for removing a predetermined thickness of the interlayer insulating film 21.

Preferably, the first SAC etching process is performed under a pressure ranging from about 10 mTorr to about 20 mTorr, at a bottom electrode power ranging from about 1200 w to about 1800 w and/or a top electrode power ranging from about 600 w to about 1500 w. In addition, the first SAC etching process may be performed using Ar gas having a flow rate ranging from about 450 sccm to about 550 sccm, C₅F₈ gas having a flow rate ranging from about 15 sccm to about 25 sccm, and/or O₂ gas having a flow rate ranging from about 15 sccm to about 19 sccm.

Also, the first SAC etching process is preferably performed at a temperature ranging from about 58° C. to about 62° C. at the upper part of an etching chamber, a temperature ranging from about 48° C. to about 52° C. on a sidewall of the etching chamber, and/or at a temperature ranging from about 38° C. to about 42° C. at an electrode in the etching chamber.

Referring to FIG. 4c, a second SAC etching process may be performed using the photoresist film pattern 25 as an etching mask.

The second SAC etching process may be performed to expose the etch barrier layer 19 while minimizing the damage to the shoulder of the insulating film spacer.

The second SAC etching process may comprise over-etching the interlayer insulating film 21 at the bottom of the contact hole. Here, the second SAC etching process comprises an over-etch process of at least about 35%.

Here, the first SAC etching process and the second SAC etching process may be carried out in an In-situ manner.

Preferably, the second SAC etching process is performed under a pressure ranging from about 10 mTorr to about 20 mTorr, at a bottom electrode power ranging from about 1200 w to about 1800 w and/or a top electrode power ranging from about 600 w to about 1500 w. In addition, the second SAC etching process may be performed using Ar gas having a flow rate ranging from about 450 sccm to about 550 sccm, C₅F₈ gas having a flow rate ranging from about 15 sccm to about 19 sccm, O₂ gas having a flow rate ranging from about 15 sccm to about 19 sccm, and/or CH₂F₂ gas having a flow rate ranging from about 2 sccm to about 10 sccm.

In addition, the second SAC etching process is preferably performed at a temperature of upper portion of a chamber ranging from about 58° C. to about 62° C., a temperature of sidewall of the chamber ranging from about 48° C. to about 52° C., and/or at a temperature of an electrode ranging from about 38° C. to about 42° C.

FIG. 4d is a top view illustrating the photoresist film pattern 25. FIGS. 4a and 4b are cross-sectional diagrams taken along the line A-A′ of FIG. 4d. FIG. 4e is cross-sectional diagram taken along the line B-B′ of FIG. 4d.

Referring to FIG. 4e, an etching process for the etch barrier layer 19 may be performed to form a contact hole.

Preferably, the etching process of the etch barrier layer 19 is performed under a pressure ranging from about 10 mTorr to about 20 mTorr, at a bottom electrode power ranging from about 1200 w to about 1800 w and/or a top electrode power ranging from about 800 w to about 1200 w. In addition, the etching process may be performed using O₂ gas having a flow rate ranging from about 150 sccm to about 250 sccm and/or Ar gas having a flow rate ranging from about 80 sccm to about 120 sccm.

In addition, the etching process of the etch barrier layer 19 is preferably performed at a temperature of upper portion of a chamber ranging from about 58° C. to about 62° C., a temperature of sidewall of the chamber ranging from about 48° C. to about 52° C., and/or at a temperature of an electrode ranging from about 38° C. to about 42° C.

Here, the etching processes illustrated in FIGS. 4a through 4e may be applied to an apparatus used for a plasma etching process.

As described above, a method for forming a contact of semiconductor device in accordance with various embodiments of the present invention minimizes the damage to the shoulder of the insulating film spacer while completely etching the interlayer insulating film at the bottom of the contact hole via two separate SAC etching processes, thereby allowing the formation of a contact hole having a stable characteristic. As a result, the characteristic and reliability of the device are improved. Accordingly, the method allows high integration of semiconductor devices.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

1. A method for forming a contact of a semiconductor device, comprising:
sequentially depositing a gate oxide film, a gate conductive layer, and a hard mask layer over a semiconductor substrate to form a stacked structure;
etching the stacked structure of the gate oxide film, the gate conductive layer, and the hard mask layer to form a gate;
forming an etch barrier layer on a surface of the semiconductor substrate including the gate;
sequentially depositing a planarized interlayer insulating film and an anti-reflective coating;
forming a photoresist film pattern exposing a contact region on the anti-reflective coating;
etching the anti-reflective coating using the photoresist film pattern as an etching mask;
performing a first self-aligned contact (SAC) etching process using the photoresist film pattern as an etching mask to etch a predetermined thickness of the interlayer insulating film;
performing a second SAC etching process using the photoresist film pattern as an etching mask to expose the etch barrier layer; and
etching the etch barrier layer to form a contact hole.

2. The method according to claim 1, wherein the gate comprises one of a word line and a bit line having an insulating film spacer on a sidewall.

3. The method according to claim 1, wherein the second SAC etching process comprises an over-etch process of at least about 35%.

4. The method according to claim 1, wherein the first SAC etching process is performed using Ar gas having a flow rate in the range of about 450 sccm to about 550 sccm, C₅F₈ gas having a flow rate in the range of about 15 sccm to about 25 sccm, and O₂ gas having a flow rate in the range of about 15 sccm to about 19 sccm under a pressure in the range of about 10 mTorr to about 20 mTorr, at a bottom electrode power in the range of about 1200 w to about 1800 w and a top electrode power in the range of about 600 w to about 500 w.

5. The method according to claim 1, wherein the second SAC etching process is performed using Ar gas having a flow rate in the range of about 450 sccm to about 550 sccm, C₅F₈ gas having a flow rate in the range of about 15 sccm to about 19 sccm, O₂ gas having a flow rate in the range of about 15 sccm to about 19 sccm, and CH₂F₂ gas having a flow rate in the range of about 2 sccm to about 10 sccm under a pressure in the range of about 10 mTorr to about 20 mTorr, at a bottom electrode power in the range of about 1200 w to about 1800 w and a top electrode power in the range of about 600 w to about 1500 w.

6. The method according to claim 1, wherein etching the etch barrier layer is performed using O₂ gas having a flow rate in the range of about 150 sccm to about 250 sccm and Ar gas having a flow rate in the range of about 80 sccm to about 120 sccm under a pressure in the range of about 10 mTorr to about 20 mTorr, at a bottom electrode power in the range of about 1200 w to about 1800 w and a top electrode power in the range of about 800 w to about 1200 w.

7. The method according to claim 1, wherein the stacked structure has a thickness of about 4000 Å.

8. The semiconductor device with the contact formed according to the method of claim 1.

9. A method for forming a contact hole of a semiconductor device, comprising:
etching a known thickness of an interlayer insulating film with a first self-aligned contact (SAC) etching process;
exposing an etch barrier layer with a second SAC etching process; and
etching the etch barrier layer to form the contact hole,
wherein the first SAC etching process and the second SAC etching process use a photoresist film pattern as an etching mask.

10. The method according to claim 9, further comprising
sequentially depositing a gate oxide film, a gate conductive layer, and a hard mask layer over a semiconductor substrate to form a stacked structure;
etching the stacked structure of the gate oxide film, the gate conductive layer, and the hard mask layer to form a gate;
forming the etch barrier layer on a surface of the semiconductor substrate including the gate; and
sequentially depositing the interlayer insulating film and an anti-reflective coating.

11. The method according to claim 10, further comprising:
forming the photoresist film pattern exposing a contact region on the anti-reflective coating; and
etching the anti-reflective coating using the photoresist film pattern as an etching mask.

12. The method according to claim 10, wherein the gate comprises one of a word line and a bit line having an insulating film spacer on a sidewall.

13. The method according to claim 10, wherein the stacked structure has a thickness of about 4000 Å.

14. The method according to claim 9, wherein the second SAC etching process comprises an over-etch process of at least about 35%.

15. The method according to claim 9, wherein the first SAC etching process is performed using Ar gas having a flow rate in the range of about 450 sccm to about 550 sccm, C₅F₈ gas having a flow rate in the range of about 15 sccm to about 25 sccm, and O₂ gas having a flow rate in the range of about 15 sccm to about 19 sccm under a pressure in the range of about 10 mTorr to about 20 mTorr, at a bottom electrode power in the range of about 1200 w to about 1800 w and a top electrode power in the range of about 600 w to about 500 w.

16. The method according to claim 9, wherein the second SAC etching process is performed using Ar gas having a flow rate in the range of about 450 sccm to about 550 sccm, C₅F₈ gas having a flow rate in the range of about 15 sccm to about 19 sccm, O₂ gas having a flow rate in the range of about 15 sccm to about 19 sccm, and CH₂F₂ gas having a flow rate in the range of about 2 sccm to about 10 sccm under a pressure in the range of about 10 mTorr to about 20 mTorr, at a bottom electrode power in the range of about 1200 w to about 1800 w and a top electrode power in the range of about 600 w to about 1500 w.

17. The method according to claim 9, wherein etching the etch barrier layer is performed using O₂ gas having a flow rate in the range of about 150 sccm to about 250 sccm and Ar gas having a flow rate in the range of about 80 sccm to about 120 sccm under a pressure in the range of about 10 mTorr to about 20 mTorr, at a bottom electrode power in the range of about 1200 w to about 1800 w and a top electrode power in the range of about 800 w to about 1200 w.

18. The semiconductor device with the contact hole formed according to the method of claim 9.
